(19) United States
(12) Patent Application Publication
(10) Pub. No.: US 2014/0055124 A1
(43) Pub. Date: Feb. 27, 2014

(54) PEAK DETECTOR AND AUTO GAIN CONTROLLER USING THE SAME

(71) Applicant: SAMSUNG ELECTRO-MECHANICS CO., LTD., Suwon (KR)

(72) Inventors: Sung Tae Kim, Suwon (KR); Young Kil Choi, Suwon (KR); Jun Kyung Na, Suwon (KR); Seung Chul Pyo, Suwon (KR); Chang Hyun Kim, Suwon (KR)

(73) Assignee: SAMSUNG ELECTRO-MECHANICS CO., LTD., Suwon (KR)

(21) Appl. No.: 13/956,809

(22) Filed: Aug. 1, 2013

(30) Foreign Application Priority Data
Aug. 27, 2012 (KR) 10-2012-093809

(51) Int. Cl. G01R 19/04

(52) U.S. Cl. CPC G01R 19/04
USPC 324/103 P

(57) ABSTRACT

Disclosed herein is a peak detector including: a operation time point providing unit outputting a certain time point before the maximum value in an interval in which a driving displacement increases as an operation time point, when a raising edge of an operation interval signal is detected; and a holding circuit unit, when a reset signal is input, starting an operation at the operation time point provided from the operation time point providing unit after an operation standby state and sensing and outputting a driving displacement of a driving mass.

### CROSS REFERENCE TO RELATED APPLICATION

This application claims the benefit of Korean Patent Application No. 10-2012-0093809, filed on Aug. 27, 2012, entitled “Peak Detector and Auto Gain Controller Using the Same”, which is hereby incorporated by reference in its entirety into this application.

### BACKGROUND OF THE INVENTION

1. Technical Field

The present invention relates to a peak detector and an auto gain controller using the same.

2. Description of the Related Art

An inertial sensor has been used in various applications, for example, military such as an artificial satellite, a missile, an unmanned aircraft, or the like, vehicles such as an air bag, electronic stability control (ESC), a black box for a vehicle, or the like, hand shaking prevention of a camcorder, motion sensing of a mobile phone or a game machine, navigation, or the like,

The inertial sensor is divided into an acceleration sensor capable of measuring linear movement and an angular velocity sensor capable of measuring rotational movement.

An acceleration in the acceleration sensor may be obtained by Newton's laws of motion “F=ma”.

Where, “m” represents a mass of moving body and “a” represents an acceleration to be measured.

In addition, the angular velocity in the angular velocity sensor may be obtained by “F=2 mΩ·v” with respect to the Coriolis force.

Where, “m” represents a mass of moving body, “Ω” represents an angular velocity to be measured, and “v” represents a motion velocity of mass. In addition, a direction of the Coriolis force is determined by a velocity (v) axis and a rotational axis of angular velocity (Ω).

The above-mentioned inertial sensor performs an auto gain control to maintain a constant performance regardless of a change in time and a surrounding environment, such that it accurately senses a target signal.

The above-mentioned auto gain control is based on a scheme controlling a gain of an auto gain controller according to a general output level. Therefore, in the case of not corresponding to an input signal variation in a signal level detection for the auto gain control at an output of a device such as cases in which other target signals are varied and other target signal levels are larger than a target signal level, the problems are solved by performing a signal level detection at a front end.

The auto gain controller should detect an output level in order to perform a gain control. To this end, one method is to detect the output level by detecting and maintaining a peak value of the output level using a peak detector.

Referring to FIG. 1, the peak detector causes a driving displacement of a driving mass to follow a peak value of amplitude of voltage waveform (Vs) having a sine wave form, such that the peak value of the amplitude of the voltage waveform (Vs) having the sine wave form becomes a driving displacement (t₁), a driving displacement (t₂), and a driving displacement (t₃) of the driving mass at a certain period (T) interval.

In this case, as is seen in the second period shown in FIG. 1, even in the case in which the peak value of the amplitude of the voltage waveform (Vs) having the sine wave is gradually reduced during the certain period (T), the driving displacement (t₂) of the driving mass detects the peak value of the amplitude of the voltage waveform (Vs) having the sine wave form of the corresponding period as the driving displacement (t₂) during the corresponding period.

In the above-mentioned peak detector, since the peak detector equally maintains the largest signal of the input signals once it is operated, reset signal should be periodically applied thereto.

The reason is that in the case in which the input signal gradually becomes large and small, it is reflected to an output of the peak detector, while in the case in which the input signal gradually becomes small, it may not be sensed.

Therefore, in the case in which the peak detector periodically applies the reset signal so as to sense again the signal level from the beginning, even in the case in which the input signal gradually becomes small, it may be sensed.

In the case in which after applying the reset signal, the reset signal is terminated, the peak detector is again normally operated.

However, when the peak detector is normally operated after the reset signal is terminated, an error may occur according to a position of where sine wave is positioned. That is, in the case in which the time point at which the peak detector is normally operated after terminating the reset is adjacent to the peak point of the sine wave, a difference between two voltages compared in a comparison unit included therein becomes large, such that current rapidly flows and the current flow in the comparison unit continues during a delay time until being turned on by a switch included in the peak detector, whereby voltage error occurs.

### PRIOR ART DOCUMENT

### Patent Document

(Patent Document 1) Japanese Patent Laid-Open Publication No. 2001-330441

### SUMMARY OF THE INVENTION

The present invention has been made in an effort to provide a peak detector and an auto gain controller using the same capable of preventing an occurrence of voltage error by deviating an operating point from a peak value.

According to a preferred embodiment of the present invention, there is provided a peak detector including: a operation time point providing unit outputting a certain time point before the maximum value in an interval in which a driving displacement increases as an operation time point, when a raising edge of an operation interval signal is detected; and a holding circuit unit, when a reset signal is input, starting an operation at the operation time point provided from the operation time point providing unit after an operation standby state and sensing and outputting a driving displacement of a driving mass.

An operation interval signal (READ) provided to the operation time point providing unit may be a step waveform having a raising edge at a falling edge of the reset signal and holding a high level during a certain time.

The operation time point providing unit, when the operation interval signal (READ) is input, may start the operation from a time point of detecting the raising edge, compares between reference voltage and the driving displacement of the driving mass to recognize a certain time point before the difference therebetween becomes the maximum value in an interval at which the driving displacement increases, thereby providing the recognized certain time point as the operation time point.

The operation time point providing unit, when the operation interval signal (READ) is input, may start the operation from a time point of detecting the raising edge and may compare between reference voltage and the driving displacement of the driving mass to recognize a time point at which the reference voltage and the driving displacement have the same value in an interval at which the driving displacement increases, thereby providing the recognized time point as the operation time point.

The operation time point providing unit may include: a first comparator receiving reference voltage and receiving the driving displacement to detect and output difference voltage (COMP OUT) therebetween; and a delay circuit receiving the operation interval signal (READ) and delaying and outputting the operation interval signal input up to a next raising edge of the difference voltage of the first comparator, thereby providing the operation time point.

The first comparator may be a differential amplifier in which an inverting terminal thereof receives certain reference voltage (Vcm) and a non-inverting terminal thereof receives the driving displacement of the driving mass to detect and output the difference voltage (COMP OUT) corresponding to the difference therebetween.

The delay circuit may be a D flip-flop in which an input terminal thereof receives the operation interval signal (READ), a clock terminal thereof receives the output signal (COMP OUT) of the first comparator, and when a clock signal input through the first comparator is changed to the raising edge, the operation interval signal is delayed and the operation time point is provided.

The holding circuit unit may include: a second comparator detecting and holding the peak value of the driving displacement of the driving mass; a first switch disposed between one terminal of the second comparator and an output terminal of the driving mass and providing the driving displacement of the driving mass to the second comparator after the operation time point; a second switch connected between the one terminal of the second comparator and a ground to allow the driving displacement of the driving mass to flow to the ground before the operation time point; a third switch disposed between a holding reference terminal and the output terminal of the second comparator and providing holding reference voltage to the output terminal before the operation time point; a fourth switch disposed between the holding reference terminal and the output terminal and switched on after the operation time point according to the output signal of the second comparator to allow the peak value of the driving displacement to output and hold through the output terminal; a fifth switch connected between the output terminal and the ground and switched on and off according to the reset signal; and a charger connected between the output terminal and the ground and also connected to the non-inverting terminal of the second comparator so as to be charged by current applied through the holding reference voltage to gradually raise the voltage level and holding the state upon reaching the peak value, when the fifth switch is switched off.

According to another preferred embodiment of the present invention, there is provided an auto gain controller including: an inertial sensor detecting an acceleration and an angular velocity of corresponding axis by a vibration of a driving mass for each axis and the Coriolis force; a driving unit vibrating the driving mass in a direction of the corresponding axis by an applied driving voltage; a peak detector, when reset signal is input, recognizing a certain time point before the maximum value in an interval at which a driving displacement increases as an operation time point, starting an operation at the recognized operation time point, and sensing and outputting the driving displacement of the driving mass; and a control unit controlling the driving unit and the peak detector.

The peak detector may include: an operation time point providing unit outputting a certain time point before the maximum value in an interval in which the driving displacement increases as the operation time point, when a raising edge of an operation interval signal is detected; and a holding circuit unit, when a reset signal is input, starting the operation at the operation time point provided from the operation time point providing unit after an operation standby state and sensing and outputting the driving displacement of the driving mass.

The auto gain controller may further include: an A/D converting unit converting an analog signal detected from the peak detector into a digital signal to transfer the converted digital signal to the control unit; and a D/A converting unit converting the digital signal input from the control unit into the analog signal to transfer the converted analog signal to the driving unit.

The auto gain controller may further include a filter unit removing noise of the converted digital signal from the A/D converting unit to transfer the converted digital signal from which the noise is removed to the control unit.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an illustrated view for describing an operation of a peak detector according to the prior art;

FIG. 2 is a configuration view of a peak detector according to a first preferred embodiment of the present invention;

FIG. 3 is a signal waveform view of the peak detector of FIG. 2

FIG. 4 is a detailed circuit view of the peak detector of FIG. 2; and

FIG. 5 is an auto gain controller using the peak detector of FIG. 2.

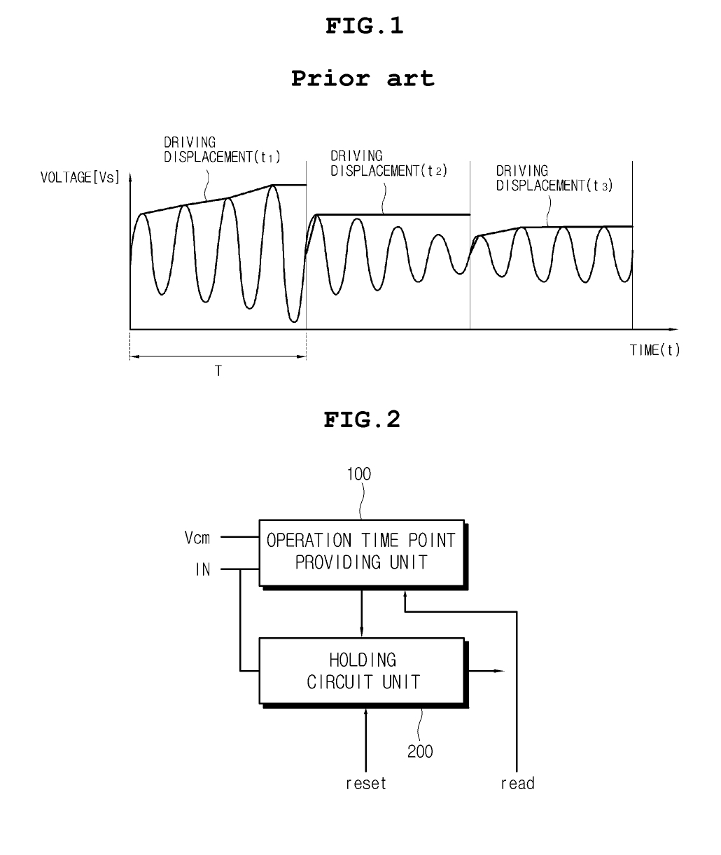

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 2 is a configuration view of a peak detector according to a first preferred embodiment of the present invention.

Referring to FIG. 2, the peak detector according to the first preferred embodiment of the present invention is configured of an operation time point providing unit 100 and a holding circuit unit 200.

In the case in which the operation time point providing unit 100 receives an operating interval signal (READ) of a step waveform which has a rising edge at a falling edge of reset signal and holds a high level during a certain time, the operation time point providing unit 100 starts an operation from the time point detecting the rising edge.

In addition, the operation time point providing unit 100 compares between reference voltage (Vcm) and a driving displacement of driving mass to recognize a certain time point before the difference therebetween becomes the maximum value in an interval in which the driving displacement increases, such that it may inform the holding circuit unit 200 of the recognized certain time point as the operation time point.

In this case, the operation time point providing unit 100 compares between the reference voltage (Vcm) and the driving displacement of the driving mass to recognize a time point at which the difference therebetween becomes zero in an interval in which the driving displacement increases, such that it may inform the holding circuit unit 200 of the recognized time point as the operation time point.

The operation time point providing unit 100 provides an operation time point providing signal (SET) of the step waveform having the rising edge changed from a low level to a high level at the operation time point to the holding circuit unit 200.

Meanwhile, when the holding circuit unit 200 receives the reset signal, it is in an operation standby state at the time point in which the reset signal is terminated and then starts again the operation at the provided operation time point in the case in which the operation time point is provided from the operation time point providing unit 100, thereby sensing again the driving displacement of the driving mass from the beginning

The operation of the peak detector according to the present invention configured as described above is as follows.

First, when the holding circuit unit 200 receives the reset signal, it holds the operation standby state at the time point at which the reset signal is terminated.

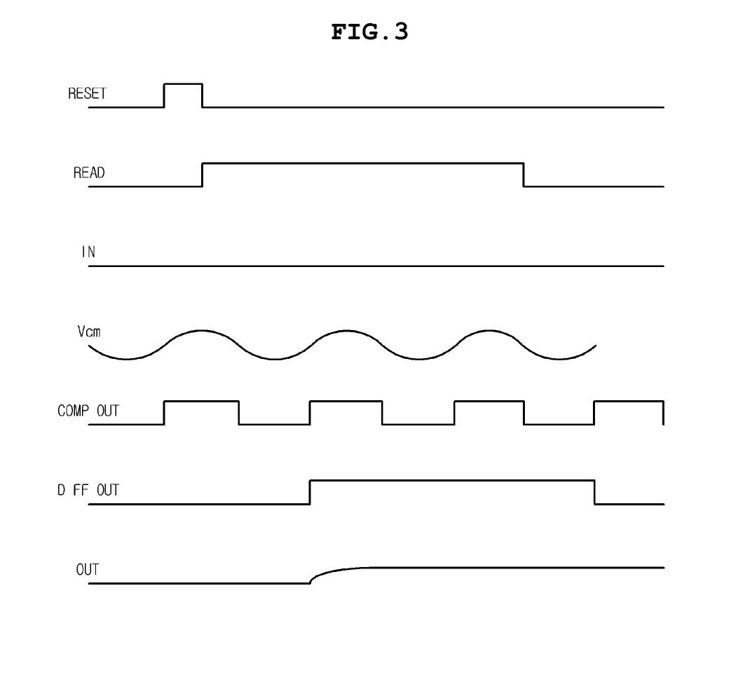

That is, when the holding circuit unit 200 receives the reset signal having the rising edge, the high level, and the falling edge as shown in FIG. 3, it is reset at the high level interval, such that it has the operation standby state at the time point at which the reset signal is terminated, that is, the falling edge.

In this case, when the operation time point providing unit 100 receives the operation interval signal (READ) of the step waveform having the rising edge at the falling edge of the reset signal and having the high level during the certain period, as shown in FIG. 3, it compares between the reference voltage (Vcm) as shown in FIG. 3 and the driving displacement (IN) of the driving mass in order to determine the operation time point of the holding circuit unit 200.

As the result of the comparison, the operation time point providing unit 100 recognizes a certain time point before the difference therebetween becomes the maximum value in the interval in which the driving displacement increases to inform the holding circuit unit 200 of the recognized certain time point as the operation time point using the operation time point providing signal (SET) of the step waveform having the raising edge changed from the low level to the high level, shown in FIG. 3.

In this case, the operation time point providing unit 100 compares between the reference voltage (Vcm) and the driving displacement of the driving mass to recognize the time point at which the difference therebetween becomes zero in the interval in which the driving displacement increases, such that it may inform the holding circuit unit 200 of the recognized time point as the operating time point.

As such, when the operation time point providing unit 100 informs the holding circuit unit 200 of the operation time point using the operation time point providing signal (SET), the holding circuit unit 200 starts the operation at the provided operation time point to sense again the driving displacement of the driving mass from the beginning.

In this case, the holding circuit unit 200 detects the maximum peak value of the amplitude of the driving displacement of the sine wave form of the driving mass to output the maximum peak value of the amplitude of the driving displacement of the sine wave form during the operation interval.

In this case, even though the peak value of the amplitude of the driving displacement of the sine wave form is gradually reduced during the operation interval, the holding circuit unit 200 detects the maximum peak value of the amplitude of the driving displacement of the sine wave form of the corresponding period of the driving mass as the output value during the corresponding period.

According to the preferred embodiment of the present invention as described above, the operation point is deviated from the peak value, thereby making it possible to prevent the occurrence of the voltage error.

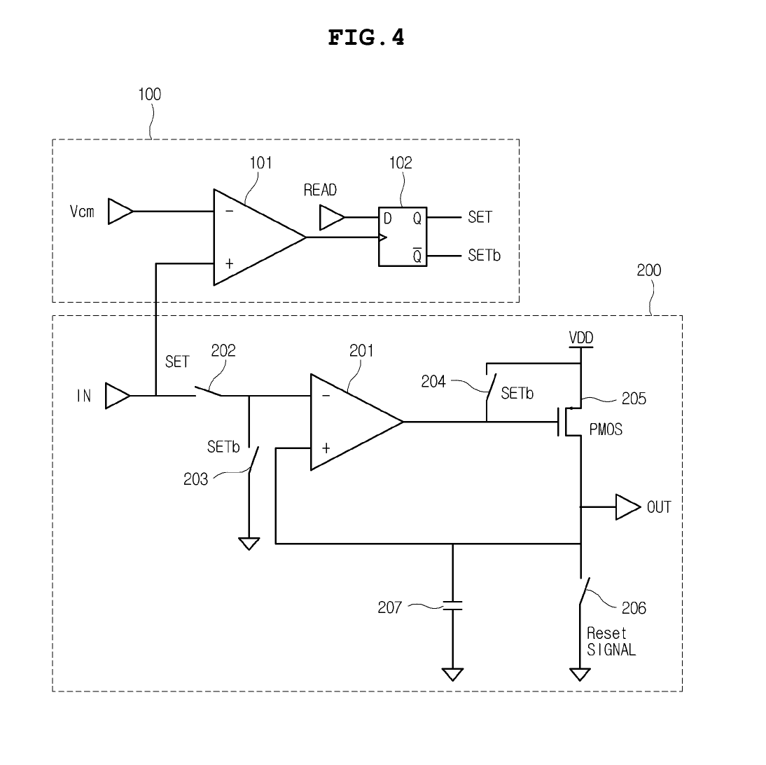

FIG. 4 is a detailed circuit view of the peak detector of FIG. 2.

Referring to FIG. 4, the peak detector of FIG. 2 includes a first comparator 101, a delay circuit 102, a second comparator 201, first to fourth switches 202 to 206, and a charger 207.

Here, the first comparator 101 and the delay circuit 102 constitute the operation time point providing unit 100. In addition, the second comparator 201, the first to fourth switches 202 to 205, and the charger 207 constitute the holding circuit unit 200.

The first comparator 101 may be implemented as a differential amplifier. As shown in FIG. 4, an inverting terminal of the first comparator 101 receives a certain reference voltage (Vcm) and a non-inverting terminal thereof receives the driving displacement of the driving mss, such that the first comparator 101 detects and outputs difference voltage (COMP OUT) corresponding to the difference therebetween. In this case, the first comparator 101 may adjust a gain value so as to amplify and output signal of the difference between the reference voltage and the driving displacement.

Next, the delay circuit 102 receives the operation interval signal (READ) of the step waveform which has the rising edge at the falling edge of the reset signal and holds the high level during a certain time and delays and outputs the input operation interval signal for a next rising edge of the difference voltage of the first comparator 101.

Here, the delay circuit 102 provides the delayed operation interval signal to the holding circuit unit 200 as the operation time point providing signal (SET), wherein the operation time point providing signal (SET) has the step waveform having the rising edge changed from the low level to the high level, as shown in FIG. 3.

In addition, the delay circuit 102 also simultaneously outputs an inverted operation time point providing signal (SETb) that the operation time point providing signal (SET) is inverted.

The above-mentioned delay circuit 102 may be implemented as a D flip-flop, wherein an input terminal of thereof receives the operation interval signal (READ) which is changed and held to the high level at the falling edge of the reset signal and a clock terminal thereof receives the output signal (COMP OUT) of the first comparator 101.

When the clock signal input through the first comparator 101 is changed to the rising edge, the above-mentioned D flip-flop delays the operation interval signal to output the delayed signal through the SET terminal and outputs high level signal.

In addition, the D flip flop output an inverted set signal that the signal of the SET terminal is inverted through an inverting terminal and outputs low level signal.

Next, the second comparator 201 detects and holds the peak value of the driving displacement of the driving mass.

The above-mentioned second comparator 201 is implemented as the differential amplifier, wherein an inverting terminal thereof receives the driving displacement of the driving mass and a non-inverting terminal thereof is connected to the charger 207.

In addition, the first switch 202 is disposed between the inverting terminal of the second comparator 201 and the output terminal of the driving mass so as to provide or block the driving displacement of the driving mass to the second comparator 201 by switching on and off.

The above-mentioned first switch 202 is implemented as a MOSFET, a JFET, a relay, or the like, and is driven according to the operation time point providing signal (SET) of the delay circuit 102.

That is, when the operation time point providing signal (SET) is the high level, the first switch 201 is switched on to provide the driving displacement of the driving mass to the inverting terminal of the second comparator 201, and when the operation time point providing signal (SET) is the low level, the first switch 201 is switched off to not provide the driving displacement of the driving mass to the second comparator 201.

Next, the second switch 203 is connected between the inverting terminal of the second comparator 201 and ground.

The above-mentioned second switch 203 is switched on and off by the inverted operation time point providing signal of the delay circuit 102, wherein when the second switch 203 is switched on, the driving displacement of the driving mass flows into the ground and when the second switch 203 is switched off, the driving displacement of the driving mass is input to the inverting terminal of the second comparator 201.

In addition, the third switch 204 is disposed between a reference terminal providing holding reference voltage (VDD) and the output terminal of the second comparator 201, and is switched on and off according to the output signal of the second comparator 201.

When the third switch 204 is switched on, the output signal becomes the holding reference voltage, and when the third switch 204 is switched off, the output voltage becomes ground signal.

Meanwhile, the fourth switch 205 is disposed between a holding reference terminal and the output terminal of the second comparator 201, and is switched on and off according to the inverted operation time point providing signal of the delay circuit 102.

When the fourth switch 205 is switched on, the fourth switch 205 applies the holding reference voltage to the third switch 204, such that the third switch 204 is switched on and off and off according to the holding reference voltage.

In addition, the fifth switch 206 is connected between the output terminal and the ground and is switched on and off according to the reset signal, wherein when the fifth switch 206 is switched on, current of the charger 207 is discharge, and the fifth switch 206 is switched off, the current is charged to the charger 207.

The charger 207 is connected between the output terminal and the ground and also connected to the non-inverting terminal of the second comparator 201.

When the fifth switch 206 is switched off, the charger 207 is charged by the current applied through the holding reference voltage to gradually raise the voltage level, and holds the state upon reaching the peak value thereof.

The operation of the peak detector configured as described above is as follows.

First, when the reset signal is applied to the fifth switch 206, the fifth switch 206 is switched on, such that the current charged in the charger 207 is discharged to the ground. Therefore, the voltage level of the charger 207 is fallen to the low level.

Meanwhile, the second switch 203 is switched on according to the inverted operation time point providing signal, such that the second comparator 201 provides the ground signal to the inverting terminal.

Therefore, the second comparator 201 outputs negative voltage according to difference signal between the voltage level of the charger 207 and the ground signal input to the inverting terminal.

In this case, the third switch 204 is switched on according to the inverted operation time point providing signal to provide the holding reference voltage (VDD) to a gate of the fourth switch 205 configured of a PMOS, such that the fourth switch 205 holds an off state and the output voltage of the second comparator 201 does not affect the fourth switch 205.

During the operation as described above, the inverting terminal of the first comparator 101 receives the certain reference voltage (Vcm) and the non-inverting terminal thereof receives the driving displacement of the driving mss, such that the first comparator 101 detects and outputs the difference voltage (COMP OUT) corresponding to the difference therebetween.

Next, the delay circuit 102 receives the operation interval signal (READ) of the step waveform which has the rising edge at the falling edge of the reset signal and holds the high level during a certain time and delays the input operation interval signal for a next rising edge of the difference voltage of the first comparator 101, thereby outputting as the operation time point providing signal.

As such, the operation time point providing signal output from the delay circuit 102 is provided to the first switch 202 to switch on the first switch 202, such that the driving displacement of the driving mass is provided to the inverting terminal of the second comparator 201.

In addition, at the same time, the inverted operation time point providing signal output from the delay circuit 102 is provided to the second switch 203 and the third switch 204 to switch off the second switch 203 and the third switch 204.

As such, when the first switch 202 is switched on, and the second switch 203 and the third switch 204 are switch off, the output of the second comparator 201 switches on and off the fourth switch 205.

In this case, since the charging voltage of the charger 207 is still at the low level, the second comparator 201 outputs the output signal of the negative voltage when the driving displacement of the driving mass increases up to the peak value.

Therefore, the fourth switch 205 is switched on and provides the current flowing by the holding reference voltage to the charger 207, thereby charging the charger 207.

With the passage of time, the charging voltage of the charger 207 increases and approaches the peak value of the driving displacement of the driving mass input through the inverting terminal of the second comparator 201.

Thereafter, the driving displacement of the driving mass descends from the peak value, wherein the driving displacement is smaller than the charging voltage charged in the charger 207.

As a result, the second comparator 201 outputs positive voltage. Therefore, the fourth switch 205 is switched off, such that the output signal output through the output terminal holds equally at the charging voltage of the charger 207.

In the peak detector as described above, the operation point is deviated from the peak value, thereby making it possible to prevent the occurrence of the voltage error.

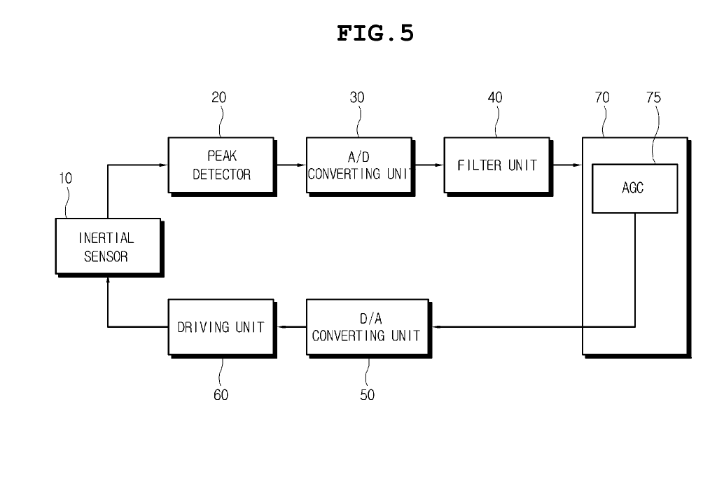

FIG. 5 is a block diagram of an auto gain controller using the peak detector of FIG. 2.

As shown in FIG. 5, the auto gain controller (AGC) using the peak detector of FIG. 2 is configured to include an inertial sensor 10, a peak detector 20, a driving unit 60 and a control unit 70 including the AGC 75.

The inertial sensor 10 may include an acceleration sensor capable of detecting an acceleration of a plurality (for, example, three) of axial directions including a driving mass or an angular velocity sensor capable of detecting an angular velocity of the plurality of axial directions. The above-mentioned inertial sensor 10 generates signal corresponding to a motion such as a movement and a rotation and the generated signal is transferred to the control unit 70 via the peak detector 20.

The driving unit 60 vibrates the driving mass in the corresponding direction by an applied driving voltage. In this case, the driving unit 60 is applied with a predetermined driving voltage according to a control of the control unit 70.

The peak detector 20, which is the peak detector 20 shown in FIG. 2, detects the driving displacement that is a variation of a motion of the driving mass resonating and vibrating in the inertial sensor 10 by the driving unit 60.

In this case, the peak detector 20 follows the peak value of the amplitude of the driving displacement (IN) of the sine wave of the driving mass as described above, wherein the peak value of the amplitude of the driving displacement (IN) of the sine wave during the operating interval becomes the driving displacement of the driving mass.

Particularly, when the peak detector 20 receives the reset signal, it is reset at the high level interval to have the operation standby state at the time point at which the reset signal is terminated, that is, the falling edge.

In this case, when the peak detector 20 receives the operation interval signal (READ) of the step waveform having the raising edge at the falling edge of the reset signal and having the high level during the certain period, it compares between the reference voltage (Vcm) and the driving displacement (IN) of the driving mass and as a result, it recognizes a certain time point before the difference therebetween becomes the maximum value to start the operation at the recognized operation time point, thereby sensing the driving displacement of the driving mass from the beginning.

The control unit 70 controls the auto gain controller overall.

Meanwhile, the auto gain controller of the inertial sensor as described above combines an analog stage and a digital stage, thereby making it possible to more precisely control the driving displacement AGC of the driving mass.

To this end, the auto gain controller may further include an A/D converting unit 30 of converting analog signal detected from the peak detector 20 into digital signal and transferring the converted signal to the control unit 70, a D/A converting unit 50 of the digital signal input from the control unit 70 into the analog signal and transferring the converted signal to the driving unit 60, and a filter unit 40 of removing noise of the digital signal converted from the A/D converting unit 30 and transferring the digital signal to the control unit 70. Here, as the filter unit 40, a low pass filter (LPF) may be used

According to the preferred embodiment of the present invention, the operating point is deviated from the peak value, thereby making it possible to prevent the occurrence of the voltage error.

In addition, in the case in which the occurrence of the voltage error of the peak detector is prevented, the detected output level is accurate, thereby making it possible to improve the performance of the auto gain controller.

As described above, the performance of the auto gain controller is improved, thereby making it possible to minimize the noise level of the gyro sensor by the auto gain controller.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A peak detector comprising:
a operation time point providing unit outputting a certain time point before the maximum value in an interval in which a driving displacement increases as an operation time point, when a raising edge of an operation interval signal is detected; and
a holding circuit unit, when a reset signal is input, starting an operation at the operation time point provided from the operation time point providing unit after an operation standby state and sensing and outputting a driving displacement of a driving mass.

2. The peak detector as set forth in claim 1, wherein an operation interval signal (READ) provided to the operation time point providing unit is a step waveform having a raising edge at a falling edge of the reset signal and holding a high level during a certain time.

3. The peak detector as set forth in claim 1, wherein the operation time point providing unit, when the operation interval signal (READ) is input, starts the operation from a time point of detecting the raising edge, compares between reference voltage and the driving displacement of the driving mass to recognize a certain time point before the difference therebetween becomes the maximum value in an interval at which the driving displacement increases, thereby providing the recognized certain time point as the operation time point.

4. The peak detector as set forth in claim 1, wherein the operation time point providing unit, when the operation interval signal (READ) is input, starts the operation from a time point of detecting the raising edge and compares between reference voltage and the driving displacement of the driving mass to recognize a time point at which the reference voltage and the driving displacement have the same value in an interval at which the driving displacement increases, thereby providing the recognized time point as the operation time point.

5. The peak detector as set forth in claim 1, wherein the operation time point providing unit includes:
a first comparator receiving reference voltage and receiving the driving displacement to detect and output difference voltage (COMP OUT) therebetween; and
a delay circuit receiving the operation interval signal (READ) and delaying and outputting the operation interval signal input up to a next raising edge of the difference voltage of the first comparator, thereby providing the operation time point.

6. The peak detector as set forth in claim 5, wherein the first comparator is a differential amplifier in which an inverting terminal thereof receives certain reference voltage (Vcm) and a non-inverting terminal thereof receives the driving displacement of the driving mass to detect and output the difference voltage (COMP OUT) corresponding to the difference therebetween.

7. The peak detector as set forth in claim 5, wherein the delay circuit is a D flip-flop in which an input terminal thereof receives the operation interval signal (READ), a clock terminal thereof receives the output signal (COMP OUT) of the first comparator, and when a clock signal input through the first comparator is changed to the raising edge, the operation interval signal is delayed and the operation time point is provided.

8. The peak detector as set forth in claim 1, wherein the holding circuit unit includes:
a second comparator detecting and holding the peak value of the driving displacement of the driving mass;
a first switch disposed between one terminal of the second comparator and an output terminal of the driving mass and providing the driving displacement of the driving mass to the second comparator after the operation time point;
a second switch connected between the one terminal of the second comparator and a ground to allow the driving displacement of the driving mass to flow to the ground before the operation time point;
a third switch disposed between a holding reference terminal and the output terminal of the second comparator and providing holding reference voltage to the output terminal before the operation time point;
a fourth switch disposed between the holding reference terminal and the output terminal and switched on after the operation time point according to the output signal of the second comparator to allow the peak value of the driving displacement to output and hold through the output terminal;
a fifth switch connected between the output terminal and the ground and switched on and off according to the reset signal; and
a charger connected between the output terminal and the ground and also connected to the non-inverting terminal of the second comparator so as to be charged by current applied through the holding reference voltage to gradually raise the voltage level and holding the state upon reaching the peak value, when the fifth switch is switched off.

9. An auto gain controller comprising:
an inertial sensor detecting an acceleration and an angular velocity of corresponding axis by a vibration of a driving mass for each axis and the Coriolis force;
a driving unit vibrating the driving mass in a direction of the corresponding axis by an applied driving voltage;
a peak detector, when reset signal is input, recognizing a certain time point before the maximum value in an interval at which a driving displacement increases as an operation time point, starting an operation at the recognized operation time point, and sensing and outputting the driving displacement of the driving mass; and
a control unit controlling the driving unit and the peak detector.

10. The auto gain controller as set forth in claim 9, wherein the peak detector includes:
an operation time point providing unit outputting a certain time point before the maximum value in an interval in which the driving displacement increases as the operation time point, when a raising edge of an operation interval signal is detected; and
a holding circuit unit, when a reset signal is input, starting the operation at the operation time point provided from the operation time point providing unit after an operation standby state and sensing and outputting the driving displacement of the driving mass.

11. The auto gain controller as set forth in claim 9, further comprising:
an A/D converting unit converting an analog signal detected from the peak detector into a digital signal to transfer the converted digital signal to the control unit; and
a D/A converting unit converting the digital signal input from the control unit into the analog signal to transfer the converted analog signal to the driving unit.

12. The auto gain controller as set forth in claim 11, further comprising:
a filter unit removing noise of the converted digital signal from the A/D converting unit to transfer the converted digital signal from which the noise is removed to the control unit.
